(19) United States
(12) Patent Application Publication
(10) Pub. No.: US 2010/0225711 A1
(43) Pub. Date: Sep. 9, 2010

(54) LIQUID EJECTING HEAD, LIQUID EJECTING APPARATUS, AND PIEZOELECTRIC ELEMENT

(75) Inventors: Jiro KATO, Suwa-shi (JP); Satoshi DENDA, Suwa-shi (JP); Ichiro ASAOKA, Chino-shi (JP)

Correspondence Address: Workman Nydegger;1000 Eagle Gate Tower, 60 East South Temple, Salt Lake City, UT, 84111, US

(73) Assignee: SEIKO EPSON CORPORATION, Tokyo (JP)

(21) Appl. No.: 12/710,715

(22) Filed: Feb. 23, 2010

(30) Foreign Application Priority Data
Mar. 4, 2009 (JP) 2009-051244

(51) Int. Cl. B41J 2/045; H01L 41/00

(52) U.S. Cl. 347/71; 310/364

(57) ABSTRACT

A liquid ejecting head is provided which includes a pressure generating room communicating with a nozzle opening, and a piezoelectric element generating a pressure change in the pressure generating room. In the above liquid ejecting head, the piezoelectric element includes a first electrode, a piezoelectric layer provided on the first electrode and having a thickness of 5 μm or less, and a second electrode provided on the piezoelectric layer at a side opposite to that of the first electrode, the piezoelectric layer contains lead, zirconium, and titanium, and a Schottky barrier value at the interface between the first electrode and the piezoelectric layer is in the range of 0.76 to 1.29 eV.

### CROSS-REFERENCE TO RELATED APPLICATIONS

This application claims the benefit of priority to Japanese Patent Application No. 2009-051244 filed Mar. 4, 2009, the contents of which are hereby incorporated by reference in their entirety.

### BACKGROUND

1. Technical Field

The present invention relates to a liquid ejecting head ejecting a liquid from a nozzle opening, a liquid ejecting apparatus, and a piezoelectric element including a first electrode, a piezoelectric layer, and a second electrode.

2. Related Art

As a piezoelectric element used for a liquid ejecting head, for example, there may be mentioned an element in which a piezoelectric layer formed of a piezoelectric material, such as a crystallized dielectric material, having an electromechanical conversion function is provided between two electrodes. The piezoelectric element as described above is mounted in a liquid ejecting head, for example, as an actuator device of a flexural oscillation mode. As a representative example of the liquid ejecting head, for example, there may be mentioned an ink jet recording head in which pressure generating rooms communicating with nozzle openings which eject ink droplets are each partially formed of a oscillation plate, and in which ink in each pressure generating room is ejected in the form of an ink droplet from the nozzle opening by deforming the oscillation plate using a piezoelectric element.

As a piezoelectric element mounted in the ink jet recording head as described above, for example, an element has been disclosed which is formed by a process including the steps of forming a uniform piezoelectric material layer over the entire surface of an oscillation plate by a film forming method, and cutting this piezoelectric material layer into shapes each corresponding to a pressure generating room by a lithography method so as to independently form piezoelectric elements for the respective pressure generating rooms (see JP-A-2003-127366, pp. 4 to 7, and FIGS. 1 to 4).

However, in a piezoelectric element having a thin piezoelectric material layer, an electric field applied to the piezoelectric element becomes high; hence, current leakage is liable to occur by a drive of the element as compared to the case of a thick piezoelectric material layer. Accordingly, when the current leakage occurs, a problem may arise in that the piezoelectric element is degraded by heat generation and/or damage done thereto. The problem as described above not only occurs in an ink jet recording head but also in a liquid ejecting head which ejects a liquid other than ink. In addition, the problem described above is not only limited to a piezoelectric element used in a liquid ejecting head, and the same problem as described above also occurs in a piezoelectric element used for another device.

### SUMMARY

An advantage of some aspects of the invention is to provide a liquid ejecting head which can suppress the current leakage of a piezoelectric element, a liquid ejecting apparatus, and a piezoelectric element.

According to a first aspect of the invention, there is provided a liquid ejecting head comprising: a pressure generating room communicating with a nozzle opening; and a piezoelectric element generating a pressure change in the pressure generating room. In the liquid ejecting head described above, the piezoelectric element includes a first electrode, a piezoelectric layer provided on the first electrode and having a thickness of 5 μm or less, and a second electrode provided on the piezoelectric layer at a side opposite to that of the first electrode, the piezoelectric layer contains lead, zirconium, and titanium, and a Schottky barrier value at the interface between the first electrode and the piezoelectric layer is in the range of 0.76 to 1.29 eV.

According to the above first aspect of the invention, in the piezoelectric element including the piezoelectric layer which contains lead, zirconium, and titanium and which has a thickness of 5 μm or less, since the Schottky barrier value at the interface between the first electrode and the piezoelectric layer is in the range of 0.76 to 1.29 eV, the leakage current from the piezoelectric element can be suppressed, for example, to 1.0×10⁻⁴ μA/cm² or less. Accordingly, the piezoelectric element can be prevented from being degraded by heat generation and/or damage done thereto, so that a liquid ejecting head having superior durability can be obtained.

In the above liquid ejecting head, the first electrode preferably contains iridium oxide and platinum. Accordingly, the leakage current from the piezoelectric element can be suppressed, and since the first electrode contains iridium oxide, components forming the piezoelectric layer can be prevented from being diffused to the first electrode and the underlayer side thereof by a high temperature heat treatment performed for forming the piezoelectric layer. In addition, since the first electrode contains platinum, the electrical conductivity of the first electrode can be ensured without degrading the electrical conductivity thereof when the piezoelectric layer is fired.

In addition, the first electrode preferably has a titanium oxide layer at a piezoelectric layer side. Accordingly, the Schottky barrier value at the interface between the first electrode and the piezoelectric layer can be easily set in the range of 0.76 to 1.29 eV.

In addition, the Schottky barrier value is preferably measured by applying an electric field of less than 400.0 V/μm. Accordingly, the leakage current can be reliably suppressed, and in addition, the piezoelectric characteristics (displacement characteristics) are not degraded.

According to a second aspect of the invention, there is provided a liquid ejecting apparatus comprising the liquid ejecting head according to the above first aspect. According to this second aspect, since the liquid ejecting head in which the leakage current from the piezoelectric element is suppressed, and in which the piezoelectric element is prevented from being degraded by heat generation and/or damage done thereto is included, a liquid ejecting apparatus having superior durability can be obtained.

In addition, according to a third another aspect of the invention, there is provided a piezoelectric element comprising: a first electrode, a piezoelectric layer provided on the first electrode and having a thickness of 5 μm or less, and a second electrode provided on the piezoelectric layer at a side opposite to that of the first electrode. In this piezoelectric element, the piezoelectric layer contains lead, zirconium, and titanium, and the Schottky barrier value at the interface between the first electrode and the piezoelectric layer is in the range of 0.76 to 1.29 eV. According to this third aspect, in the piezoelectric element comprising a piezoelectric layer which contains lead, zirconium, and titanium, and which has a thickness of 5 μm or less, since the Schottky barrier value at the interface with the first electrode is in the range of 0.76 to 1.29 eV, the leakage current can be suppressed, for example, to 1.0 μA/cm² or less.

### BRIEF DESCRIPTION OF THE DRAWINGS

The invention will be described with reference to the accompanying drawings, wherein like numbers reference like elements.

FIG. 1 is an exploded perspective view showing a schematic structure of a recording head according to Embodiment 1.

FIGS. 2A and 2B are plan view and a cross-sectional view, respectively, of the recording head according to Embodiment 1.

FIGS. 3A to 3C are cross-sectional views each showing a method for manufacturing the recording head according to Embodiment 1.

FIGS. 4A to 4C are cross-sectional views each showing the method for manufacturing the recording head according to Embodiment 1.

FIGS. 5A to 5D are cross-sectional views each showing the method for manufacturing the recording head according to Embodiment 1.

FIGS. 6A and 6B are cross-sectional views each showing the method for manufacturing the recording head according to Embodiment 1.

FIG. 7 is a view showing results of Test Example 1.

FIG. 8 is a view showing results of Test Example 1.

FIG. 9 is a view showing results of Test Example 1.

FIG. 10 is a view showing results of Test Example 1.

FIG. 11 is a view showing results of Test Example 2.

FIG. 12 is a perspective view showing a schematic structure of a recording head according to one embodiment of the invention.

### DESCRIPTION OF EXEMPLARY EMBODIMENTS

### Embodiment 1

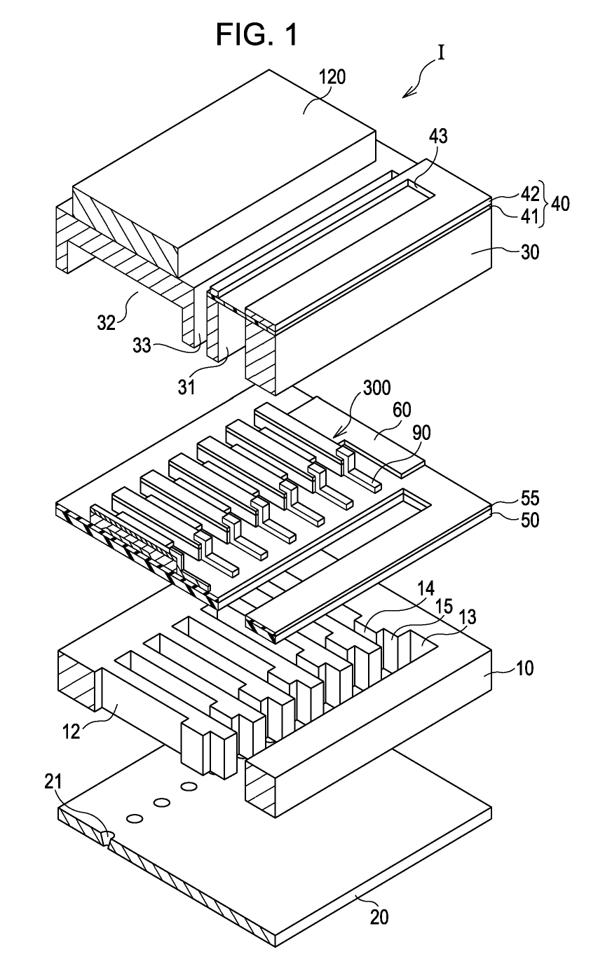

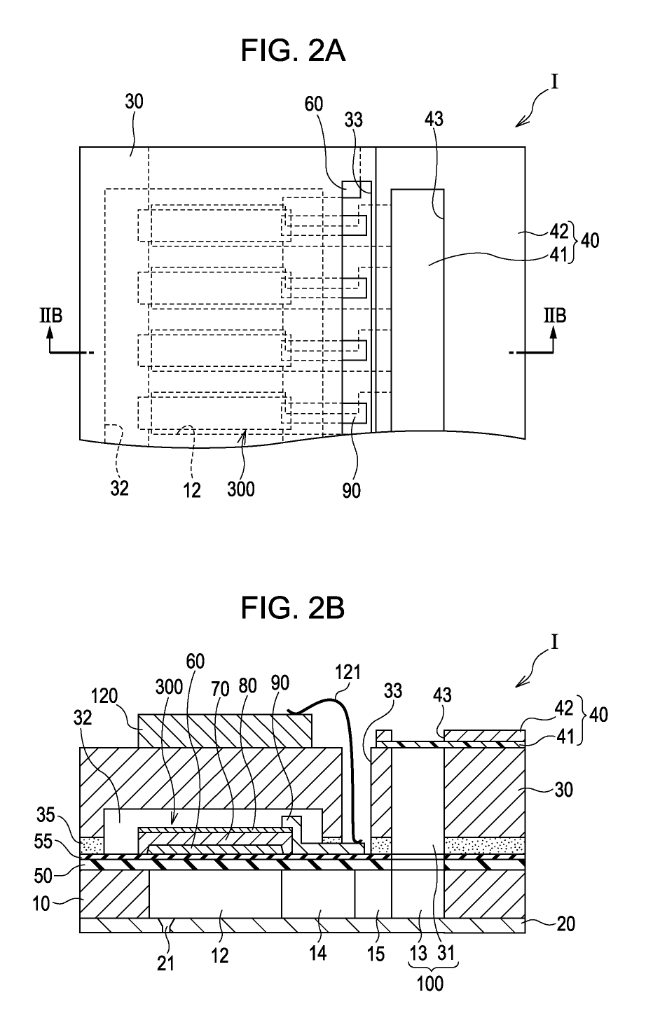

FIG. 1 is an exploded perspective view showing a schematic structure of an ink jet recording head which is one example of a liquid ejecting head according to Embodiment 1 of the invention, and FIGS. 2A and 2B are respectively a plan view of FIG. 1 and a cross-sectional view thereof taken along the line IIB-IIB.

As shown in FIGS. 1, 2A, and 2B, a flow path forming substrate 10 of this embodiment is formed of a silicon single crystal substrate, and on one surface thereof, an elastic film 50 is formed.

In the flow path forming substrate 10, a plurality of pressure generating rooms 12 is formed in parallel in a width direction thereof. In addition, a communicating portion 13 is formed in a region of the flow path forming substrate 10 outside in a longitudinal direction of the pressure generating rooms 12, and the communicating portion 13 communicates with each of the pressure generating rooms 12 with an ink supply path 14 and a communicating path 15 interposed therebetween, which are provided for each pressure generating room 12. The communicating portion 13 communicates with a reserver portion 31 of a protective substrate which will be described later to form a part of a reserver used as a common ink chamber for the pressure generating rooms 12. The ink supply path 14 is formed to have a width smaller than that of the pressure generating room 12 and maintains a flow path resistance of an ink constant which flows from the communicating portion 13 to the pressure generating room 12. In addition, in this embodiment, the ink supply path 14 is formed by narrowing the width of a flow path from one side thereof; however, the ink supply path 14 may be formed by narrowing the width of the flow path from both sides thereof. In addition, without narrowing the width of the flow path, the ink supply path may be formed by narrowing the flow path in a thickness direction. In the flow path forming substrate 10 according to this embodiment, there is provided liquid flow paths each formed of the pressure generating room 12, the communicating portion 13, the ink supply path 14, and the communicating path 15.

In addition, a nozzle plate 20 having nozzle openings 21 formed therein, which communicate with the pressure generating rooms 12, in the vicinities of end portions thereof opposite to the ink supply paths 14 is fixed to an opening surface side of the flow path forming substrate 10 by an adhesive, a heat welding film, or the like. In addition, the nozzle plate 20 is formed, for example, of a glass ceramic, a silicon single crystal substrate, or a stainless steel sheet.

In addition, at the side opposite to the opening surface of the flow path forming substrate 10, the elastic film 50 is formed as described above, and an insulating film 55 is formed thereon. Furthermore, on this insulating film 55, a first electrode 60, piezoelectric layers 70 having a thickness of 5 μm or less and preferably 1 to 5 μm, and second electrodes 80 are laminated to form piezoelectric elements 300. The piezoelectric element 300 is a portion including the first electrode 60, the piezoelectric layer 70, and the second electrode 80. In general, one of the electrodes of the piezoelectric element 300 is used as a common electrode, and the other electrode and the piezoelectric layer 70 are formed by patterning for each pressure generating room 12. In this embodiment, the first electrode 60 is used as the common electrode of the piezoelectric elements 300, and the second electrode 80 is used as a discrete electrode for the corresponding piezoelectric element 300; however, for example, in consideration of positions or the like of a drive circuit and/or wires, the first and the second electrodes may be used in an opposite way to that described above. In addition, the piezoelectric element 300 and an oscillation plate which is displaced by the drive thereof are collectively called an actuator device. In the example described above, although the elastic film 50, the insulating film 55, and the first electrode 60 each function as the oscillation plate, of course, the oscillation plate is not limited thereto, and for example, only the first electrode 60 may be designed to function as the oscillation plate without providing the elastic film 50 and the insulating film 55. In addition, the piezoelectric element 300 may be designed so as to actually function also as the oscillation plate.

In this embodiment, the first electrode 60 contains iridium oxide (IrOₓ) and platinum (Pt) and further has a titanium oxide layer primarily composed of titanium oxide (TiOₓ) at a piezoelectric layer 70 side. In this case, although the titanium oxide layer will be described later in detail, this layer is formed when seed titanium used for forming the piezoelectric element 300 is oxidized and has a rutile structure. In addition, since the first electrode 60 contains iridium oxide, components forming the piezoelectric layer 70 are prevented from being diffused to the first electrode 60 and the underlayer side thereof, and since platinum is contained, the electrical conductivity of the first electrode 60 can be sufficiently ensured.

In addition, the piezoelectric layer 70 on the first electrode 60 is formed of a piezoelectric material having an electromechanical conversion function, contains lead, zirconium, and titanium, and for example, has a perovskite structure. As the piezoelectric layer 70, for example, a ferroelectric material, such as lead zirconate titanate (PZT), or a compound which is formed by adding a metal oxide, such as niobium oxide, nickel oxide, or magnesium oxide, to the above ferroelectric material is preferably used. In particular, lead zirconate titanate (Pb(Zr,Ti)O₃), lead lanthanum zirconate titanate ((Pb,La)(Zr,Ti)O₃), lead magnesium niobate zirconate titanate (Pb(Zr,Ti)(Mg,Nb)O₃) or the like may be used. In addition, the second electrode 80 is formed of iridium (Ir) or the like.

In addition, in the invention, the Schottky barrier value at the interface between the first electrode 60 and the piezoelectric layer 70 is in the range of 0.76 to 1.29 eV. When the Schottky barrier value at the interface between the first electrode 60 and the piezoelectric layer 70 is set in the range of 0.76 to 1.29 eV as described above, the leakage current of the piezoelectric element 300 can be suppressed. Hence, degradation of the piezoelectric element 300 caused by heat generation and/or damage done thereto can be prevented. In addition, in an ink jet recording head in which a plurality of piezoelectric elements 300 is arranged, the current leakage may occur in some piezoelectric element 300 due to variation in manufacturing; however, it is difficult to discriminate a piezoelectric element 300 in which the leakage occurs. However, by a simple method in which the Schottky barrier value is controlled, the generation of leakage can also be evaluated. In addition, when the Schottky barrier value is less than 0.76 eV, the leakage current is high, and when the Schottky barrier value is more than 1.29 eV, the voltage is not applied to the piezoelectric layer 70, so that the piezoelectric displacement cannot be obtained.

As a factor determining the leakage current of the piezoelectric element 300, a factor resulting from the interface state between the first electrode and the piezoelectric layer 70 and a factor resulting from the bulk state instead of the interface state, that is, a factor resulting from the piezoelectric layer 70 itself, may be mentioned. In addition, as the factor resulting from the interface state, there are Schottky Emission current (J=A·T²·Exp[−(e·φ_{B}−β_{SE}√E)/(K_{B}T)]) and Fowler-Nordheim tunneling current (J=A·E²·Exp[−B/E]). In addition, as the factor resulting from the bulk state, there are Poole-Frenkel current (J=A·E·Exp[−(e·φₜ−β_{PF}√E)/(kBT)]) and Space-charge-limited current (J=A·E+B·(E−E₀)²). In the above equations, J indicates a leakage current, E indicates an electric field to be applied, A, B, and E₀ are constants, φ_{B} indicates a Schottky barrier value, β_{SE} indicates a Schottky constant, φₜ indicates a trap level, and β_{PF} indicates a Poole-Frenkel constant. Among those described above, in general, it is difficult to clearly discriminate a dominating factor of leakage current of the piezoelectric element 300.

However, according to the structure of this embodiment, that is, in particular, according to the piezoelectric element 300 which includes a piezoelectric layer containing lead, zirconium, and titanium and having a thickness of 5 μm or less, since the Schottky Emission current resulting from the interface state is a dominating factor of leakage current of the piezoelectric element 300, when the Schottky barrier value is set in the range of 0.76 to 1.29 eV, the leakage current can be suppressed. In other words, according to the invention, the piezoelectric element 300 is formed so that the first electrode 60 and the piezoelectric layer 70 form a Schottky junction and the dominating factor of leakage current is the Schottky Emission current, and the Schottky barrier value is set in the range of 0.76 to 1.29 eV; hence, the leakage current is suppressed. In addition, in the piezoelectric element 300 of the invention, since the Fowler-Nordheim tunneling current, the Poole-Frenkel current, and the Space-charge-limited current are not the dominating factor of leakage current, even if the values based on the Fowler-Nordheim tunneling current, the Poole-Frenkel current, and the Space-charge-limited current are defined, it is difficult to suppress the leakage current.

If the dominating factor of leakage current results from the bulk state as the Poole-Frenkel current instead of resulting from the interface state as in the invention, in order to suppress the leakage current, a material itself for the piezoelectric layer 70 is to be adjusted. When the material for the piezoelectric layer 70 is adjusted to obtain a desired leakage current, the piezoelectric characteristics (displacement characteristics) are considerably influenced, and as a result, the degree of design freedom of piezoelectric characteristics is decreased. On the other hand, according to the invention, since the leakage current is suppressed by controlling the Schottky barrier value between the first electrode 60 and the piezoelectric layer 70 to a predetermined value, the influence on the piezoelectric characteristics is reduced as compared to the case in which only the piezoelectric layer 70 is adjusted, that is, as compared to the case in which the dominating factor of leakage current results from the bulk state; hence, the adjustment can be easily performed so as to enable the piezoelectric layer 70 to exhibit desired piezoelectric characteristics. In addition, even when the piezoelectric layer 70 is not adjusted, the Schottky barrier can also be adjusted to a predetermined value.

In addition, the Schottky barrier value can be adjusted not only by the type of piezoelectric layer 70 but also by the type of first electrode 60, and when the first electrode 60 has a titanium oxide layer, the Schottky barrier value can be further adjusted by the thickness of the titanium oxide layer, the degree of oxidation thereof, and the balance therebetween. In addition, the Schottky barrier value can be obtained by a general method, and in particular, by a method disclosed in J. Appl. Phy., Vol. 92, No. 10, 15 Nov., 2002, p. 6160.

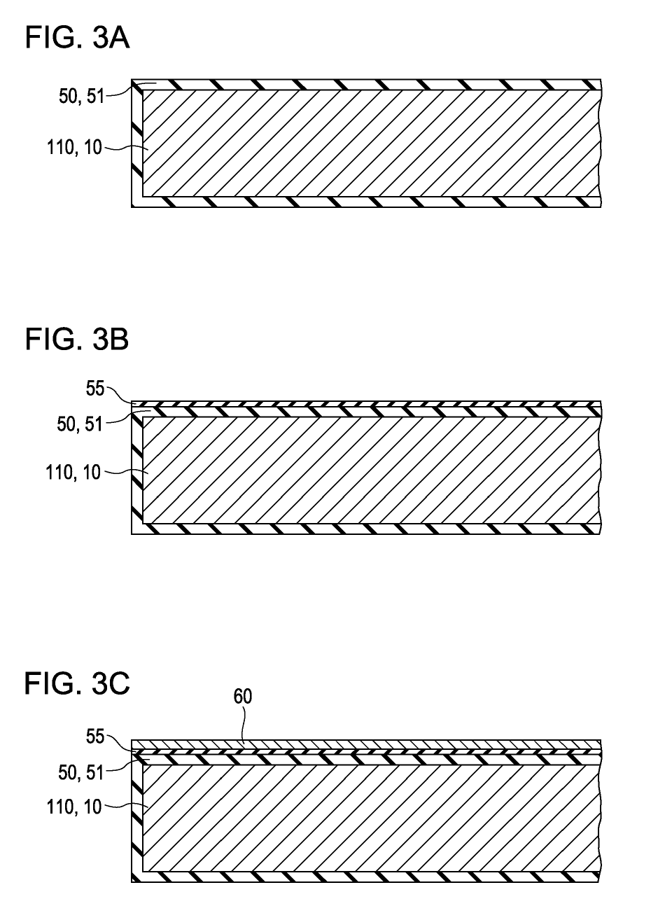

Although a method for forming the piezoelectric elements 300 as described above on the flow path forming substrate 10 is not particularly limited, for example, the following method may be used for manufacturing. In addition, FIGS. 3A to 6B are cross-sectional views of a pressure generating room in a longitudinal direction thereof, which show a method for manufacturing an ink jet recording head according to Embodiment 1 of the invention. First, as shown in FIG. 3A, a silicon dioxide film 51 primarily composed of silicon dioxide (SiO₂) is formed on the surface of a flow path forming-substrate wafer 110 which is a silicon wafer to form the elastic film 50. Next, as shown in FIG. 3B, the insulating film 55 made of zirconium oxide or the like is formed on the elastic film 50 (silicon dioxide film 51).

Next, as shown in FIG. 3C, the first electrode 60 containing a platinum layer and an iridium layer laminated thereon is formed by a sputtering method or the like. The platinum layer is selected as a material which does not lose its electrical conductivity even when a heat treatment is performed at a high temperature in a subsequent step to form a piezoelectric layer film 70 which is to be formed into the piezoelectric layers 70. In addition, the iridium layer is a layer to prevent components forming the piezoelectric layer film 70 from being diffused to the first electrode 60 and the underlayer side thereof by the heat treatment at a high temperature which is performed to form the piezoelectric layer film 70.

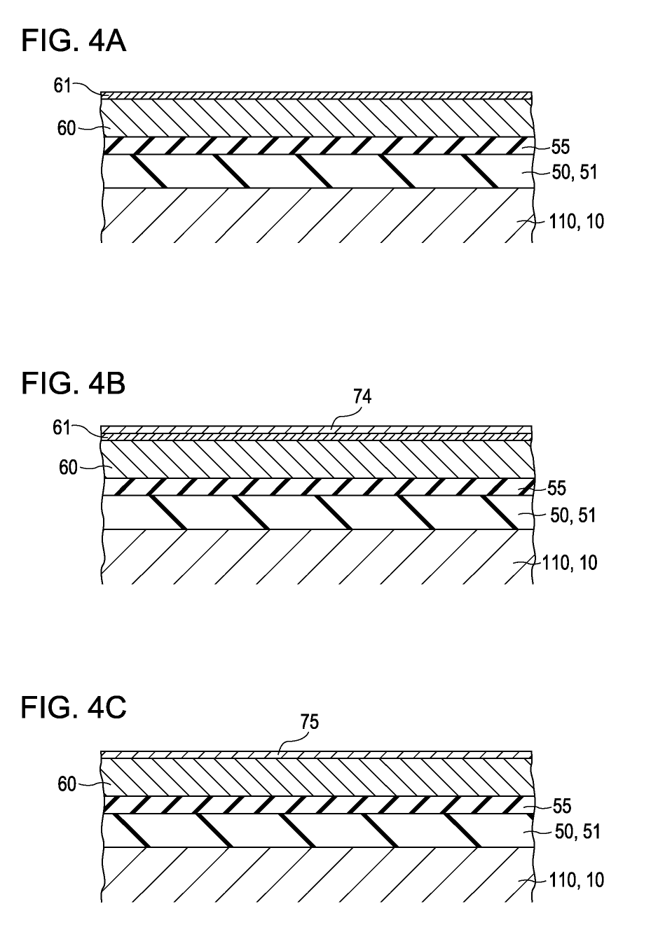

Next, as shown in FIG. 4A, a seed titanium layer 61 made of titanium (Ti) is formed on the first electrode 60 by a sputtering method or the like. Since the seed titanium layer 61 is formed on the first electrode 60, when the piezoelectric layer film 70 is formed in a subsequent step on the first electrode 60 with the seed titanium layer 61 interposed therebetween, the piezoelectric layer film 70 can be controlled so that the degree of orientation in the (100) plane is high, such as 80% or more, and the piezoelectric layer film 70 can be obtained which is suitably used for forming an electromechanical conversion element. In addition, when the piezoelectric layer film 70 is crystallized, the seed titanium layer 61 functions as a seed for promoting the crystallization, and since being simultaneously heated when the piezoelectric layer film 70 is fired, the seed titanium layer 61 is partially diffused in the piezoelectric layer film 70. In addition, when the piezoelectric layer film 70 is fired, the seed titanium layer 61 partially remains and is oxidized, so that a titanium oxide layer is finally generated to form a part of the first electrode 60.

Subsequently, the piezoelectric layer film 70 is formed on the first electrode 60. In this embodiment, the piezoelectric layer film 70 is obtained by a so-called sol-gel method. In this sol-gel method, a so-called sol in which a metal organic substance is dissolved and/or dispersed in a solvent is applied and dried to form a gel, and firing is further performed at a high temperature to form the piezoelectric layer film 70 from the metal organic substance. The method for manufacturing the piezoelectric layer film 70 is not limited to a sol-gel method, and a metal-organic decomposition (MOD) method may also be used. In addition, although the piezoelectric layer film 70 can also be formed by a sputtering method, a chemical vapor deposition (CVD) method, or a printing method, when the piezoelectric layer film 70 is formed by the method mentioned above, since the Schottky Emission current may not be a dominating factor of leakage current of the piezoelectric element 300 in some cases, the material and manufacturing conditions of the piezoelectric layer film 70 must be adjusted so that the Schottky Emission current becomes a dominating factor of leakage current.

As a particular procedure for forming the piezoelectric layer film 70, first, as shown in FIG. 4B, a piezoelectric precursor film 74 which is a precursor film of the piezoelectric layer film is formed on the first electrode (seed titanium layer 61). That is, a sol (solution) containing Pb, Ti, and Zr is applied on the flow path forming substrate 10 which is provided with the first electrode 60 thereon (application step). Next, this piezoelectric precursor film 74 is heated to a predetermined temperature and is dried for a predetermined time (drying step). Next, the piezoelectric precursor film 74 thus dried is heated to a predetermined temperature and is held for a predetermined time, so that degreasing is performed (degreasing step). The “degreasing” in this embodiment indicates that organic components contained in the piezoelectric precursor film 74 are removed, for example, in the form of NO₂, CO₂, H₂O, and the like.

Subsequently, as shown in FIG. 4C, the piezoelectric precursor film 74 is heated to a predetermined temperature and is held for a predetermined time for crystallization, so that a first-layer piezoelectric film 75 is formed (firing step).

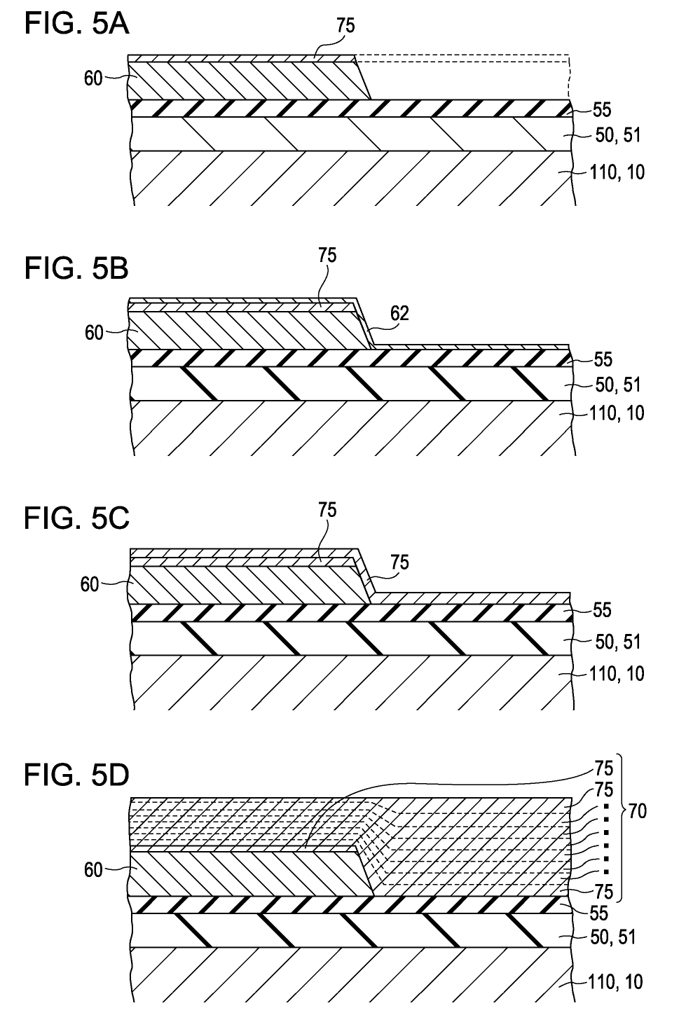

Next, as shown in FIG. 5A, at the stage at which the first-layer piezoelectric film 75 is formed, the first electrode 60 and the first-layer piezoelectric film 75 are simultaneously patterned. Subsequently, as shown in FIG. 5B, after an intermediate titanium layer 62 made of titanium (Ti) is again formed over the entire surface of the flow path forming-substrate wafer 110 including the first-layer piezoelectric film 75, a piezoelectric-film forming process including the above-described application step, drying step, degreasing step, and firing step is performed, so that a second-layer piezoelectric film 75 is formed as shown in FIG. 5C. In addition, as shown in FIG. 5D, the piezoelectric-film forming process including the above-described application step, drying step, degreasing step, and firing step is repeatedly performed, so that the piezoelectric layer film 70 including a plurality of the piezoelectric films 75 is formed.

Subsequently, in the firing step of forming the piezoelectric layer film 70, the above-described platinum, iridium, and titanium are oxidized, alloyed, and mixed, so that the first electrode 60 is formed. In this embodiment, “alloying” indicates the state in which a metal element and another metal element form a metal bond therebetween, and “mixing” indicates the state in which a metal element and another metal element form no metal bond therebetween.

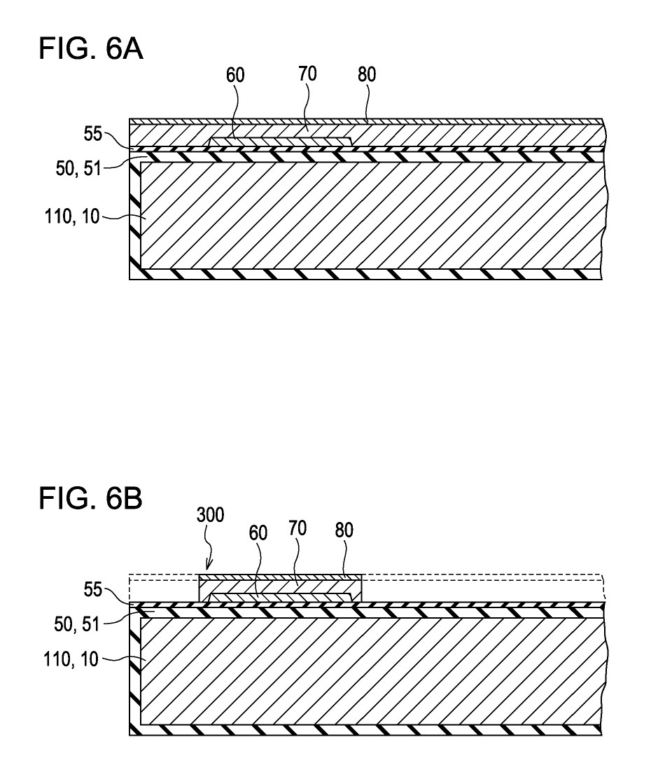

Next, as shown in FIG. 6A, after a second electrode film 80, which is to be formed into the second electrodes 80, made of iridium (Ir) or the like is formed over the piezoelectric layer film 70, as shown in FIG. 6b, the piezoelectric layer film 70 and the second electrode film 80 are pattern-etched into regions corresponding to the pressure generating rooms 12, so that the piezoelectric elements 300 are formed.

In the above method for forming the piezoelectric elements 300 on the flow path forming substrate 10, the Schottky barrier value at the interface between the first electrode 60 and the piezoelectric layer 70 changes not only depending on the material, thickness, composition, and manufacturing conditions, such as a firing temperature, of the piezoelectric layer film 70, that is, on the type of piezoelectric layer film 70, but also depending on the material, thickness, composition, and manufacturing conditions, such as a firing temperature, of the first electrode 60, that is, on the type of first electrode 60. Furthermore, the above Schottky barrier value also changes depending on the balance between the items mentioned above. In addition, when the first electrode 60 has a titanium oxide layer, the above Schottky barrier value also changes depending on the thickness and the degree of oxidation of the titanium oxide layer.

### Example 1

The piezoelectric elements 300 were formed on the flow path forming substrate 10 by the method described above. In this example, the seed titanium layer 61 was formed and was then completely oxidized in an atmosphere having an oxygen concentration of approximately 30 volume percent into titanium oxide having a rutile structure. In addition, the piezoelectric layer film 70 made of lead zirconate titanate was formed on the titanium oxide having a rutile structure. In this example, after the first-layer piezoelectric film 75 was formed, titanium oxide having a rutile structure similar to that of the seed titanium layer 61 was formed as the intermediate titanium layer 62, and the second-layer piezoelectric film 75 was formed on the intermediate titanium layer 62. The firing temperature of the piezoelectric layer film 70 was 700° C.

### Example 2 and Comparative Example 1

By adjusting various manufacturing conditions, a plurality of piezoelectric elements 300 was manufactured which have different Schottky barrier values at the interface between the first electrode 60 and the piezoelectric layer 70.

In Example 2, the thickness of the seed titanium layer 61 was decreased (2 nm), and titanium oxide obtained by oxidation in firing was adjusted so as to be nonuniform due to oxidation expansion of the iridium layer present under the titanium oxide. As a result, the structure was formed in which the piezoelectric layer 70 and iridium thus oxidized were partially and directly bonded to each other.

In Comparative Example 1, the thickness of the seed titanium layer 61 was increased (10 nm), and a part of the seed titanium layer (in the vicinity of the first piezoelectric film 75) was converted into titanium oxide having a rutile structure in firing, so that the structure was formed in which titanium, which was not oxidized, was present in the vicinity of the substrate.

### Comparative Example 2

The procedure similar to that of Example 1 was performed except that the iridium layer of the first electrode 60 and the seed titanium layer 61 were not formed, and the first electrode 60 was formed of platinum having a thickness of 130 nm.

### Test Example 1

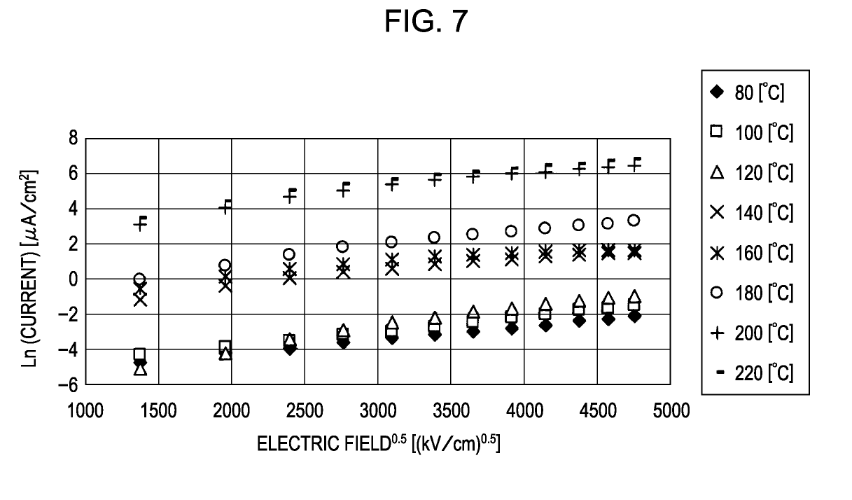

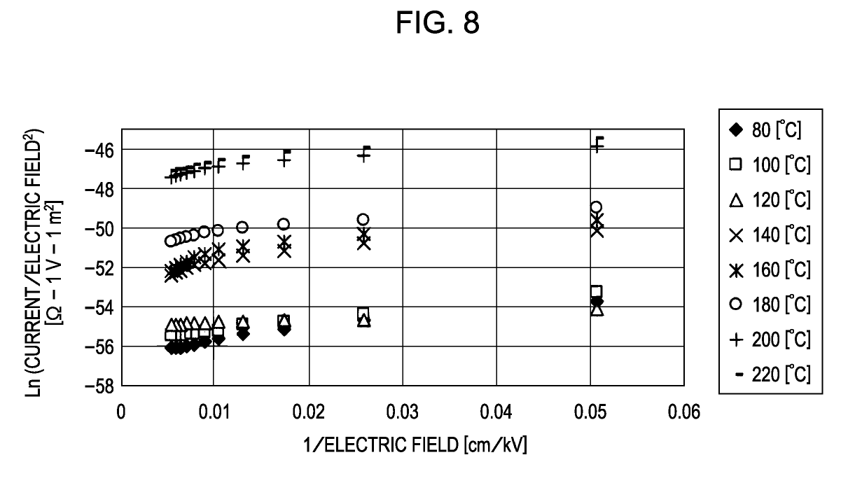

The leakage current was measured by applying an electric field to the piezoelectric element 300 of Example 1, and the relationship between the electric field and the leakage current was plotted as shown in FIGS. 7 and 8. In FIG. 7, the horizontal axis indicates (electric field)^{0.5}, the vertical axis indicates the natural logarithm of current, and as the relationship is closer to a linear line, it indicates that the Schottky Emission current is a dominating factor. In FIG. 8, the horizontal axis indicates (1/electric field), the vertical axis indicates the natural logarithm of (current/(electric field)²), and as the relationship is closer to a linear line, it indicates that the Fowler-Nordheim tunneling current is a dominating factor.

In FIG. 7, the relationship shows an approximately linear behavior, and hence it is understood that the Schottky Emission current resulting from the interface state is a dominating factor of leakage current of the piezoelectric element 300 according to Example 1. On the other hand, in FIG. 8, the relationship does not shows a linear behavior, and hence it is understood that the Fowler-Nordheim tunneling current is not a dominating factor of leakage current of the piezoelectric element 300 according to Example 1. In addition, in Example 2 and Comparative Example 1 in which the piezoelectric elements 300 were manufactured in a manner similar to that of Example 1, it is believed that the Schottky Emission current is a dominating factor of leakage current of the piezoelectric element 300.

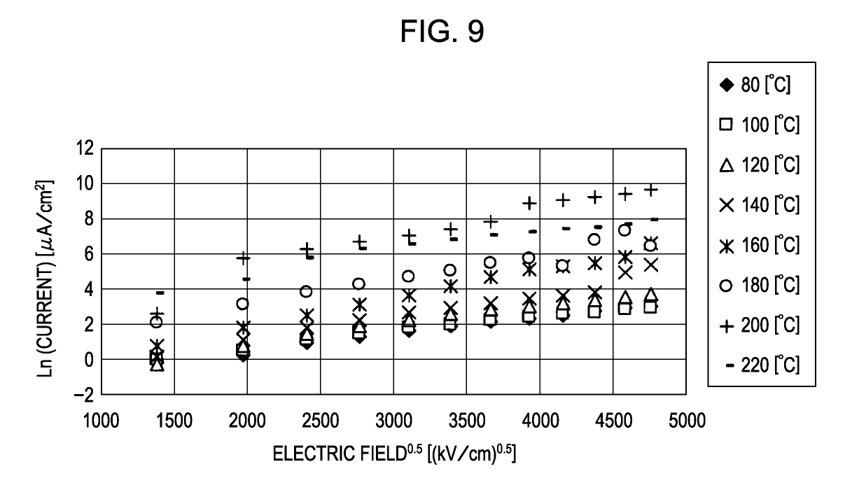

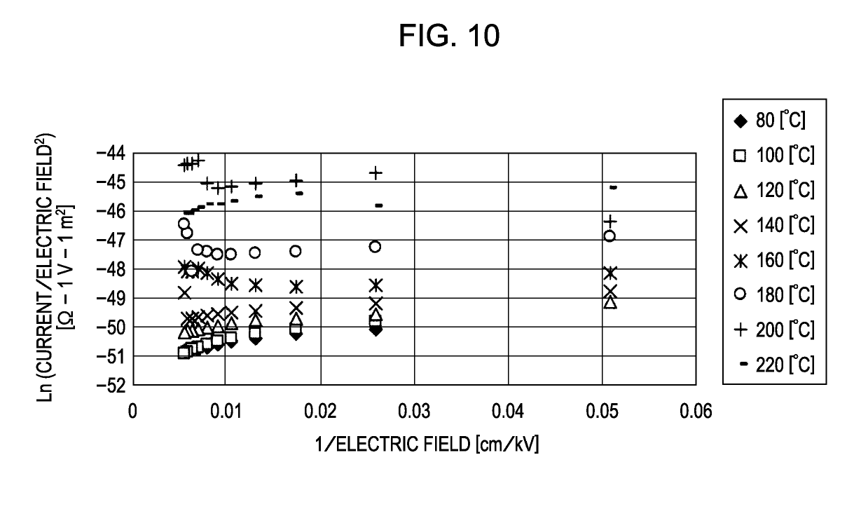

In addition, the leakage current of the piezoelectric element of Comparative Example 2 was measured by applying an electric field thereto, and the relationship between the electric field and the leakage current was plotted as shown in FIGS. 9 and 10.

As shown in FIG. 9, the relationship shows an approximately linear behavior, and hence it is understood that also in the piezoelectric element of Comparative Example 2 in which the iridium oxide layer and the titanium oxide layer are not provided, the Schottky Emission current resulting from the interface state is a dominating factor of leakage current.

### Test Example 2

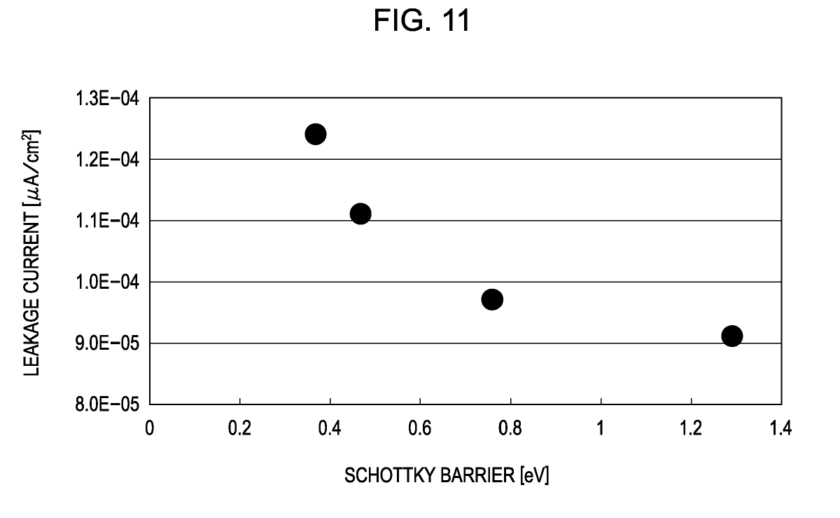

The Schottky barrier values of the piezoelectric elements 300 of Examples 1 and 2 and Comparative Examples 1 and 2 were measured. In order to obtain preferable measurement results having high reproducibility, the measurement electric field is preferably set in the range of 75 to 400 kV/cm. In addition, when the measurement temperature is set in the range of 120° C. to 240° C., the Schottky barrier value can be precisely measured. When the measurement is performed after 5 minutes or more from the change in voltage, the Schottky barrier value can be stabilized. In addition, an electric field of 189 V/μm was applied at a measurement temperature of 27° C., and the leakage current of the piezoelectric element 300 was measured. The results are shown in Table 1 and FIG. 11.

TABLE 1

| | | | Comparative | Comparative |
|---|---|---|---|---|
| | Example 1 | Example 2 | Example 1 | Example 2 |
| Schottky | 1.29 | 0.76 | 0.37 | 0.47 |
| barrier [eV] | | | | |
| Leakage current | 9.1 × 10⁻⁵ | 9.7 × 10⁻⁵ | 12.4 × 10⁻⁵ | 1.11 × 10⁻⁴ |
| [μA/cm²] | | | | |

As shown in Table 1 and FIG. 11, the Schottky barrier value changes depending on the thickness and presence/absence of the seed titanium layer 61 and the firing conditions of the piezoelectric layer film 70, and the leakage currents of Examples 1 and 2 in which the Schottky barrier value is in the range of 0.76 to 1.29 eV are significantly low as compared to the leakage currents of the Comparative Examples 1 and 2. As apparent from these results, when the Schottky barrier value is set in the range of 0.76 to 1.29 eV, the leakage current can be suppressed.

A lead electrode 90 made of gold (Au) or the like which extends on the insulating film 55 from the vicinity of the end portion of the piezoelectric element 300 at an ink supply path 14 side is connected to the second electrode 80 which is a discrete electrode of the piezoelectric element 300.

On the flow path forming substrate 10 on which the piezoelectric elements 300 are formed, that is, on the first electrode 60, the insulating film 55, and the lead electrodes 90, a protective substrate 30 having the reserver portion 31 which forms at least part of a reserver 100 is bonded with an adhesive 35 interposed therebetween. In this embodiment, this reserver portion 31 is formed to penetrate the protective substrate 30 in a thickness direction thereof and to extend in the width direction of the pressure generating room 12. Accordingly, this reserver portion 31 communicates with the communicating portion 13 of the flow path forming substrate 10 as described above to form the reserver 100 which is a common ink chamber for the pressure generating rooms 12. In addition, the communicating portion 13 of the flow path forming substrate 10 may be divided into a plurality of portions for the respective pressure generating rooms 12 so that only the reserver portion 31 is used as the reserver. Furthermore, for example, only the pressure generating rooms 12 may be provided in the flow path forming substrate 10, and the ink supply paths 14 communicating with the reserver and the pressure generating rooms 12 may be provided in a member (such as the elastic film 50 and/or the insulating film 55) provided between the flow path forming substrate 10 and the protective substrate 30.

In addition, a piezoelectric element holding portion 32 having a space so as not to disturb the movement of the piezoelectric elements 300 is provided in a region of the protective substrate 30 facing the piezoelectric elements 300. The piezoelectric element holding portion 32 may have a space so as not to disturb the movement of the piezoelectric elements 300, and the space may be either tightly sealed or not.

For the protective substrate 30 described above, a material having a coefficient of thermal expansion approximately equivalent to that of the flow path forming substrate 10, such as a glass or a ceramic material, is preferably used, and in this embodiment, the protective substrate 30 is formed using a silicon single crystal substrate which is the same material as that for the flow path forming substrate 10.

In addition, in the protective substrate 30, a penetrating hole 33 penetrating the protective substrate 30 in the thickness direction thereof is provided. In addition, the end portion of the lead electrode 90 extending from each piezoelectric element 300 is provided so as to be exposed in the penetrating hole 33.

In addition, a drive circuit 120 to drive the piezoelectric elements 300 which are disposed in parallel is fixed on the protective substrate 30. As this drive circuit 120, for example, a circuit substrate, a semiconductor integrated circuit (IC), or the like may be used. In addition, the drive circuit 120 is electrically connected to the lead electrodes 90 with connection wires 121 made of electrical conductive wires, such as bonding wires, provided therebetween.

In addition, a compliance substrate 40 formed of a sealing film 41 and a fixing plate 42 is bonded on the protective substrate 30 described above. In this embodiment, the sealing film 41 is formed from a flexible material having a low rigidity, and one direction of the reserver portion 31 is sealed by this sealing film 41. In addition, the fixing plate 42 is formed of a relatively hard material. Since a region of this fixing plate 42 facing the reserver 100 is completely removed in a thickness direction to form an opening portion 43, the one direction of the reserver 100 is sealed only by the flexible sealing film 41.

In the ink jet recording head according to this embodiment, after an ink is supplied through an ink inlet connected to an ink supply device (not shown) located outside and is filled inside from the reserver 100 to the nozzle openings 21, a voltage is applied between the first electrode 60 and the second electrode 80 in the corresponding pressure generating room 12 in accordance with a recording signal from the drive circuit 120 to flexurally deform the elastic film 50, the insulating film 55, the first electrode 60, and the piezoelectric layer 70, and hence the pressure inside the pressure generating room 12 is increased, so that an ink droplet is ejected from the nozzle opening 21.

### Other Embodiments

Heretofore, although one embodiment of the invention has been described, the fundamental structure of the invention is not limited to that described above. For example, although the first electrode 60 which contains platinum and iridium oxide and which has a titanium oxide layer at the piezoelectric layer 70 side is described by way of example, materials for the first electrode 60 are not particularly limited, and for example, the first electrode 60 may be formed to contain no iridium oxide and/or to include no titanium oxide layer. In addition, a titanium oxide layer may be provided on the insulating film 55 as an adhesion layer to improve the adhesion force between the first electrode 60 and the insulating film 55 provided thereunder as an underlayer.

In addition, in Embodiment 1 described above, although a silicon single crystal substrate having a (110) crystal plane orientation is described as the flow path forming substrate 10 by way of example, a material for the flow path forming substrate 10 is not particularly limited thereto, and for example, a silicon single crystal substrate having a (100) crystal plane orientation may be used, or an SOI substrate or a material such as a glass may also be used.

Furthermore, in Embodiment 1 described above, although the piezoelectric element 300 in which the first electrode 60, the piezoelectric layer 70, and the second electrode 80 are sequentially laminated on the substrate (flow path forming substrate 10) is described by way of example, the piezoelectric element 300 is not particularly limited thereto, and for example, the invention may also be applied to a longitudinal oscillation type piezoelectric element in which a piezoelectric material and an electrode forming material are alternately laminated so as to be expanded and contracted in an axis direction.

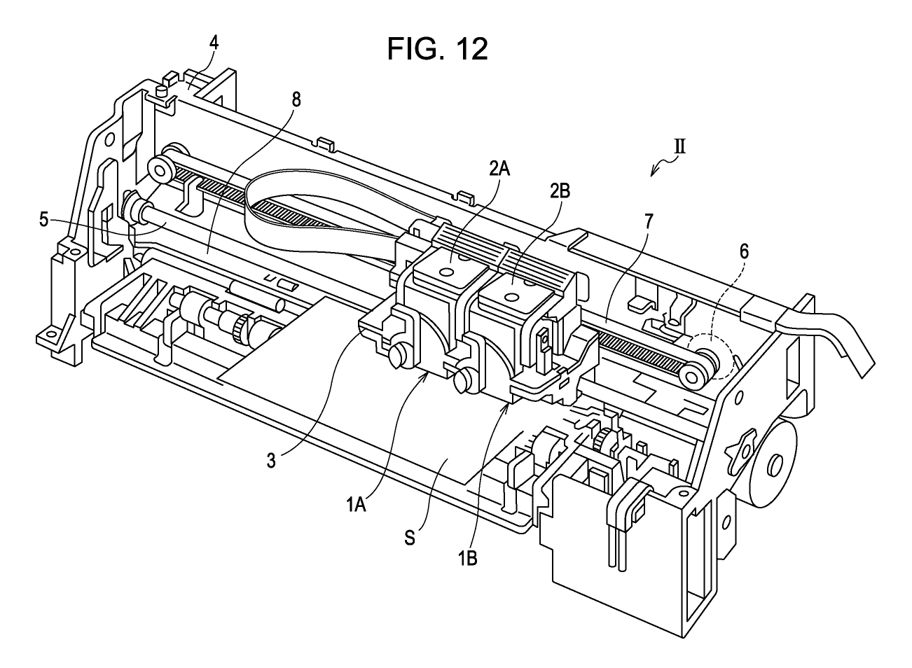

In addition, the ink jet recording heads of the embodiments described above each partially form a recording head unit having an ink flow path which communicates with an ink cartridge or the like, and are each mounted in an ink jet recording apparatus. FIG. 12 is a schematic view showing one example of the ink jet recording apparatus.

In an ink jet recording apparatus II shown in FIG. 12, recording head units 1A and 1B each including an ink jet recording head I are detachably provided with cartridges 2A and 2B, respectively, which form ink supply devices, and a carriage 3 mounting these recording head units 1A and 1B is provided on a carriage shaft 5 fitted to a main frame body 4 so as to freely move along the shaft direction. The recording head units 1A and 1B are formed so as to eject, for example, a black ink composition and a color ink composition, respectively.

In addition, when a drive force of a drive motor 6 is transmitted to the carriage 3 through a plurality of gears (not shown) and a timing belt 7, the carriage 3 mounting the recording head units 1A and 1B is moved along the carriage shaft 5. In addition, a platen 8 is provided in the main frame body 4 along the carriage shaft 5, and a recording sheet S, which is a recording medium, such as paper, and which is fed by a paper feed roller (not shown) or the like, is wound around the platen 8 so as to be transported.

In the above Embodiment 1, as one example of the liquid ejecting head, the ink jet recording head is described; however, since the invention has been conceived so as to be widely applied to any types of liquid ejecting heads, of course, the invention may also be applied to liquid ejecting heads ejecting liquids other than ink. As other liquid ejecting heads, for example, there may be mentioned various recording heads used in image recording apparatuses, such as a printer; color material ejecting heads used for manufacturing color filters of a liquid crystal display and the like; electrode material ejecting heads used for forming electrodes of an organic EL display, a field emission display (FED), and the like; and bioorganic material ejecting heads used for forming biochips.

In addition, besides piezoelectric elements to be mounted in a liquid ejecting head represented by an ink jet recording head, the invention may also be applied to piezoelectric elements to be mounted in other apparatuses.

What is claimed is:

1. A liquid ejecting head comprising:
a pressure generating room communicating with a nozzle opening; and
a piezoelectric element generating a pressure change in the pressure generating room,
wherein the piezoelectric element includes a first electrode, a piezoelectric layer provided above the first electrode and having a thickness of 5 μm or less, and a second electrode provided above the piezoelectric layer,
the piezoelectric layer contains lead, zirconium, and titanium, and
a Schottky barrier value at the interface between the first electrode and the piezoelectric layer is in the range of 0.76 to 1.29 eV.

2. The liquid ejecting head according to claim 1, wherein the first electrode contains iridium oxide and platinum.

3. The liquid ejecting head according to claim 1, wherein the first electrode has a titanium oxide layer at a piezoelectric layer side.

4. The liquid ejecting head according to claim 1, wherein the Schottky barrier is measured by application of an electric field of less than 400.0 V/μm.

5. A liquid ejecting apparatus comprising:
the liquid ejecting head according to claim 1′.

6. A piezoelectric element comprising:
a first electrode, a piezoelectric layer provided on the first electrode and having a thickness of 5 μm or less, and a second electrode provided on the piezoelectric layer at a side opposite to that of the first electrode,
wherein the piezoelectric layer contains lead, zirconium, and titanium, and
a Schottky barrier value at the interface between the first electrode and the piezoelectric layer is in the range of 0.76 to 1.29 eV.

7. A liquid ejecting apparatus comprising:
the liquid ejecting head according to claim 2.

8. A liquid ejecting apparatus comprising:
the liquid ejecting head according to claim 3.

9. A liquid ejecting apparatus comprising:
the liquid ejecting head according to claim 4.
